(19) United States
(12) Patent Application Publication
(10) Pub. No.: US 2020/0135846 A1
(43) Pub. Date: Apr. 30, 2020

(54) Termination structure of MOSFET and fabricating method thereof

(71) Applicant: He Ding Technology Co., Ltd., New Taipei City (TW)

(72) Inventor: Yuan-Shun CHANG, New Taipei City (TW)

(21) Appl. No.: 16/421,592

(22) Filed: May 24, 2019

(30) Foreign Application Priority Data
Oct. 24, 2018 (TW) 107137622

(51) Int. Cl. H01L 29/06; H01L 21/28; H01L 21/02

(52) U.S. Cl. CPC H01L 29/0623; H01L 29/78; H01L 21/02129; H01L 21/28194

(57) ABSTRACT

A termination structure of MOSFET and a fabricating method thereof are provided. The fabricating method includes: forming a doped zone on a semiconductor substrate; forming trench rings in the doped zone; forming a gate oxide layer in each trench ring;

depositing a polycrystalline silicon above the gate oxide layer; carrying out a back etching process of the polycrystalline silicon to form two self-aligned island polycrystalline silicon zones on two side walls of each of the trench rings, the two island polycrystalline silicon zones being not contact with each other; forming an insulation oxide layer in each of the trench rings; and covering the doped zone with a metal layer, and laying out the metal layer to form a discontinuous metal layer.

### TECHNICAL FIELD

The instant disclosure relates to a termination structure of MOSFET and a fabricating method thereof and, more particularly, to a termination structure of MOSFET having a middle-high guard ring and fabricating method thereof.

### RELATED ART

Metal oxide semiconductor field effect transistors (MOSFETs) are widely applied to switching components of electric devices, e.g., power supplies, rectifiers, or low-voltage motor controllers. Nowadays, most of MOSFETs have vertical structure design, e.g., a trench MOSFET, to increase the density of components. In general, a MOSFET has a design of a main zone and a termination (also called terminal zone). The main zone has transistor components. The termination is at a periphery of the main zone to increase the level of withstand voltage of component periphery. A usual design of the termination is to form multiple guard rings by well zones, such that the electric filed of the termination can be decreased to make a breakdown point of the component occur in the main zone. In order to maintain the level of breakdown voltage of the main zone as a whole, it is better to ensure the breakdown voltage in the termination (which is lateral breakdown voltage) being greater than the breakdown voltage in the main zone (which is vertical breakdown voltage).

Regarding a known termination structure of the guard ring formed by the well zone, the depth of the guard ring (i.e., the depth of the well zone) and the breakdown voltage are in direct ratio. The increasing of the depth of the guard ring can increase the breakdown voltage. Nonetheless, concerning the fabricating process of semiconductors, the greater the depth of the well zone is, the more the thermal budge for carrying out implantation and diffusion of impurity is required. Therefore, the withstand voltage and the thickness of the epitaxial layer are also in direct ration. Such fabricating process requires thicker epitaxial layer to fabricate products in practice, and such choice would increase the on-resistance of the products. It is harmful to fabrication.

### SUMMARY

To address the above issue, the instant disclosure aims to provide a termination structure of MOSFET having a middle-high breakdown voltage and being unaffected by the depth of a guard ring and fabricating method thereof.

To achieve the above objectives, the instant disclosure provides a fabricating method of a termination structure of MOSFET, comprising steps of: forming a doped zone on a semiconductor substrate; forming a plurality of trench rings in the doped zone; forming a gate oxide layer in each of the trench rings; depositing a polycrystalline silicon above the gate oxide layer; carrying out a back etching process of the polycrystalline silicon to form two self-aligned island polycrystalline silicon zones on two side walls of each of the trench rings, the two island polycrystalline silicon zones being not contact with each other; forming an insulation oxide layer in each of the trench rings; and covering the doped zone with a metal layer, and laying out the metal layer to form a discontinuous metal layer.

In an embodiment, the step of forming the trench rings in the doped zone comprises steps of: depositing a hard mask above the doped zone; forming a patterned photoresist on the hard mask; laying out the hard mask to form the trench rings by the patterned photoresist; and carrying out a dry etching process to form e trench rings in the doped zone.

In an embodiment, after the step of forming the trench rings in the doped zone and before the step of forming the gate oxide layer in each of the trench rings, the fabricating method further comprises a step of: forming a sacrifice oxide layer in each of the trench rings and then removing the sacrifice oxide layer.

In an embodiment, after the step of forming the insulation oxide layer in each of the trench rings and before the step of covering the doped zone with the metal layer, the fabricating method further comprises steps of: forming a patterned photoresist on the insulation oxide layer; carrying out an etching process of the exposed insulation oxide layer on a main zone of the MOSFET by the patterned photoresist to form a contact window and then removing the patterned photoresist; and forming a source polycrystalline silicon zone and a heavily doped zone on the doped zone of the main zone via the contact window.

In an embodiment, the step of forming the insulation oxide layer in each of the trench rings comprises steps of: forming an inner-layer dielectric (ILD) layer in each of the trench rings; and forming a boro-phospho-silicate glass (BPSG) layer on the inner-layer dielectric layer.

In an embodiment, the step of laying out the metal layer to form the discontinuous metal layer comprises steps of: depositing the metal layer above the doped zone; forming the patterned photoresist above the metal layer; carrying out an etching process of the metal layer by the patterned photoresist and then removing the patterned photoresist; and forming the discontinuous metal layer.

The instant disclosure also provides a termination structure of MOSFET comprising a semiconductor substrate, a doped zone, a gate oxide layer, two island polycrystalline silicon zones, an insulation oxide layer, and a discontinuous metal layer. The doped zone is formed on the semiconductor substrate. The doped zone comprises a plurality of trench rings. The gate oxide layer is ⁻formed in each of the trench rings. The two island polycrystalline silicon zones are formed on the gate oxide layer of two side walls of each of the trench rings. The two island polycrystalline silicon zones do not contact with each other. The insulation oxide layer covers above the two island polycrystalline silicon zones. The discontinuous metal layer is formed above the gate oxide layer and the insulation oxide layer doped zone and the trench ring.

In an embodiment, the two island polycrystalline silicon zones are made of polycrystalline silicon, doped polycrystalline silicon, metal, amorphous silicon, or the combination thereof, and the gate oxide layer is made of silica.

In an embodiment, the semiconductor substrate comprises a substrate and an epitaxial layer. The epitaxial layer is formed above the substrate.

In an embodiment, the insulation oxide layer comprises an inner-layer dielectric layer and a boro-phospho-silicate glass layer. The boro-phospho-silicate glass layer is formed above the inner-layer dielectric layer.

### BRIEF DESCRIPTION OF THE DRAWINGS

FIG. 1A to FIG. 1D illustrate schematic cross sectional views of forming trench rings in steps of a fabricating process in sequence according to an embodiment of the instant disclosure;

FIG. 24 and FIG. 2B illustrate schematic cross sectional views of forming and removing a sacrifice oxide layer in steps of a fabricating process in sequence according to an embodiment of the instant disclosure;

FIG. 3A to FIG. 3C illustrate schematic cross sectional views of forming island polycrystalline silicon zones in steps of a fabricating process in sequence according to an embodiment of the instant disclosure;

FIG. 44 to FIG. 4C illustrate schematic cross sectional views of forming an insulation oxide layer, a source polycrystalline silicon zone, and a heavily doped zone in steps of a fabricating process in sequence according to an embodiment of the instant disclosure; and

FIG. 5A to FIG. 5C, illustrate schematic cross sectional views of forming a discontinuous metal layer in steps of a fabricating process in sequence according to an embodiment of the instant disclosure.

### DETAILED DESCRIPTION

In the drawings, for showing clearly, relative thicknesses and positions of layers, zones, and/or components of structures may be smaller or larger comparing to their actual states, and some known components are omitted.

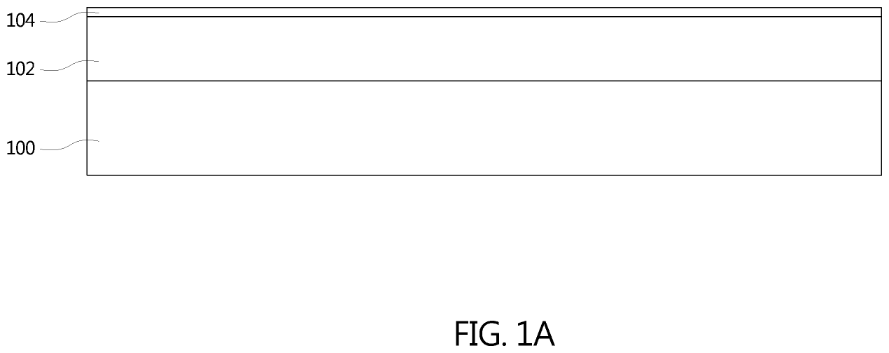

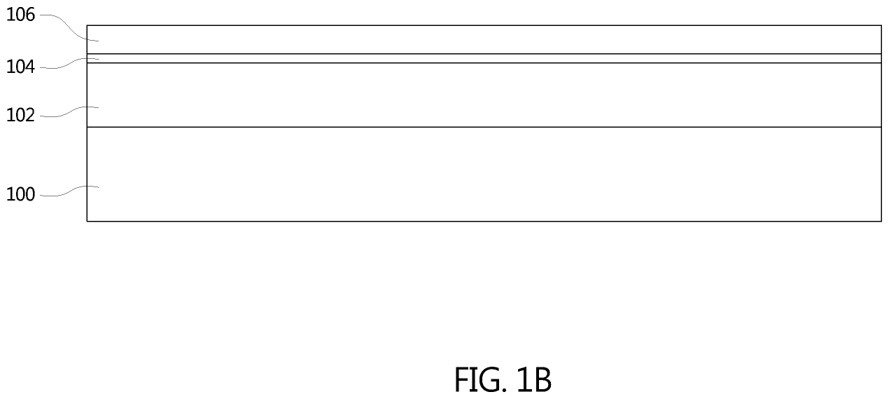

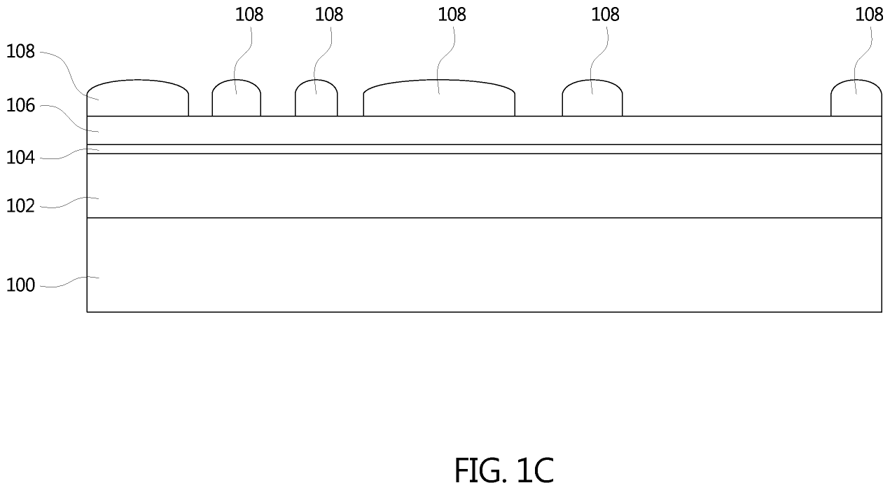

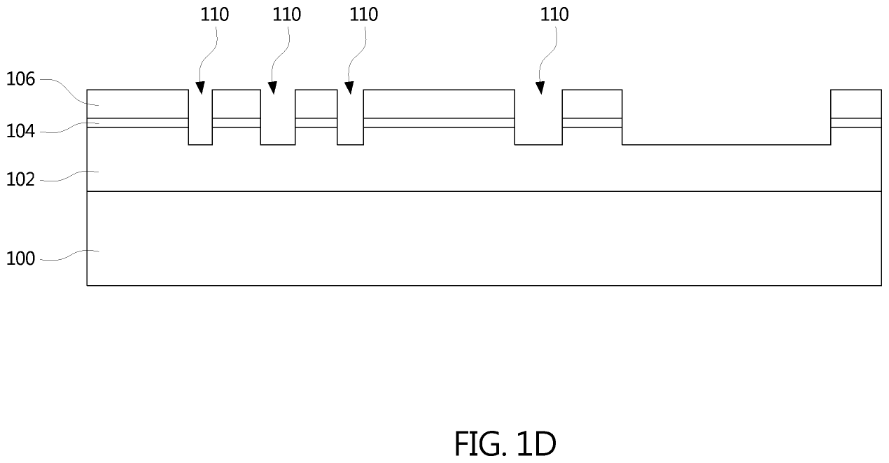

FIG. 1A to FIG. 1D are schematic cross sectional views of forming trench rings 110 in steps of a fabricating process in sequence according to an embodiment of the instant disclosure. Wherein, the leftmost periphery is a periphery of a main zone of a MOSFET. As shown in FIG. 1A, in the embodiment, a semiconductor substrate is provided, The semiconductor substrate may comprise a substrate 100 and an epitaxial layer 102. The substrate 100 is formed by ion implanting a first conductive type heavily doped element into a silicon substrate. The epitaxial layer 102 epitaxially grows above the substrate 100 and is formed by a first conductive type soft doped element in an ion implantation manner. For instance, in an embodiment, the first conductive type is N type, and the second conductive type is P type. In another embodiment, the first conductive type is P type, and the second conductive type is N type. Next, as shown in FIG. 1B, a process of blanket body implantation and drive-in is carried out to form a second conductive type doped zone 104 along the epitaxial layer 102 in advance, e.g., a P type well zone is formed above the epitaxial layer 102. Then a hard mask 106 is deposited above the doped zone 104. Next, as shown in FIG. 1C, a photoresist is applied above the hard mask 106, and a mask is used to carry out an exposing and developing process to form a patterned photoresist 108. Next, as 2.5 shown in FIG II), an etching process of the exposed hard mask 106 is carried out by the patterned photoresist 108 in advance, and then the patterned photoresist 108 is removed. Trench rings are laid out by the hard mask 106 to define a position and scope of the trench rings. The etched and left hard mask 106 is used as a mask to carry out an etching process (e.g., a dry etching process) of the exposed doped zone 104 and the epitaxial layer 102 beneath thereof Further, a plurality of trench rings 110 is formed on the doped zone 104. The trench rings 110 are at a termination, are independent from one another, and are around a periphery of the main zone.

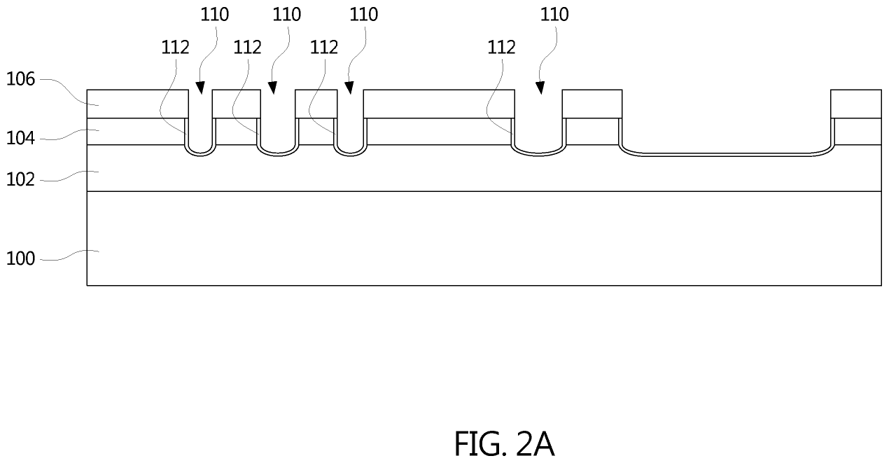

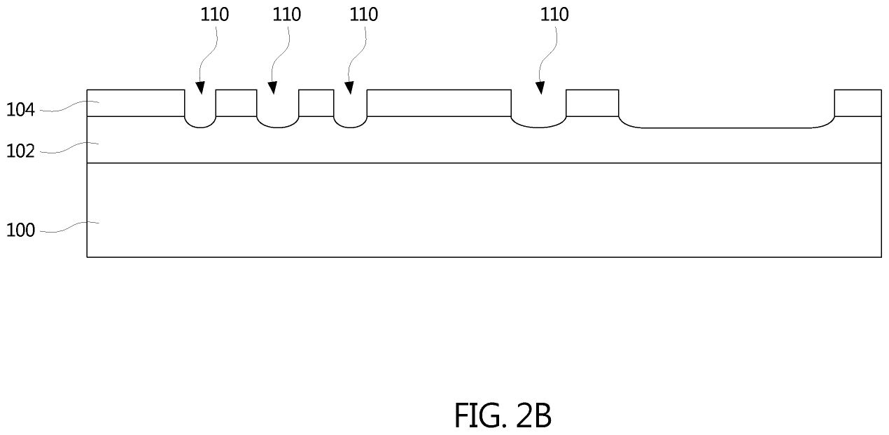

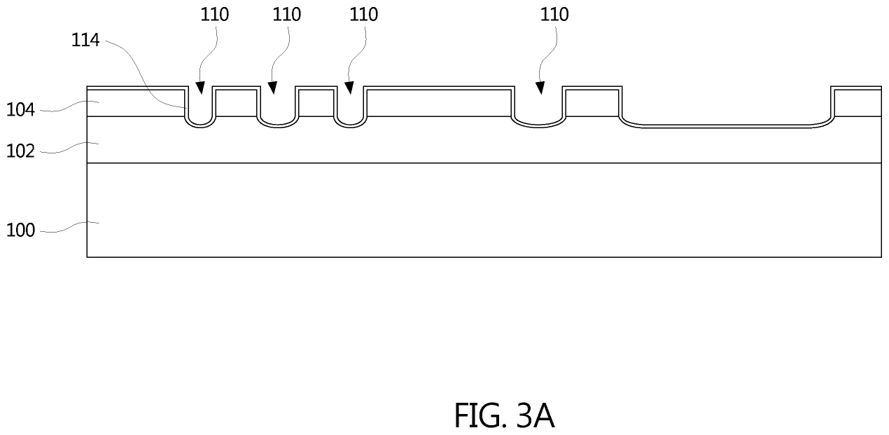

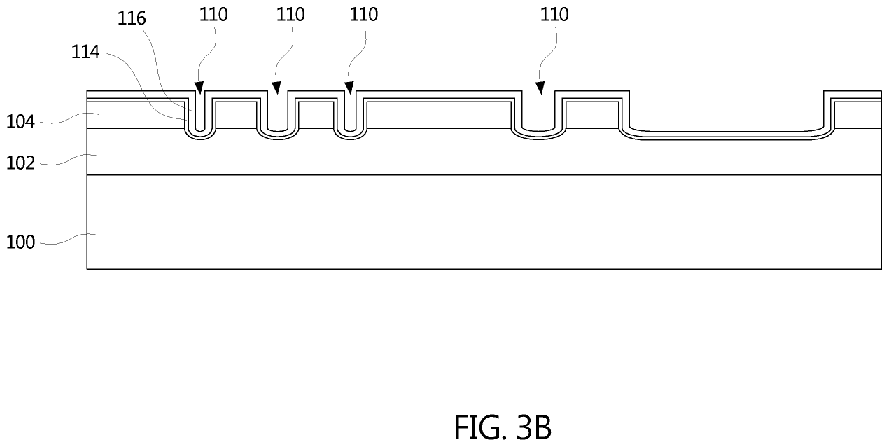

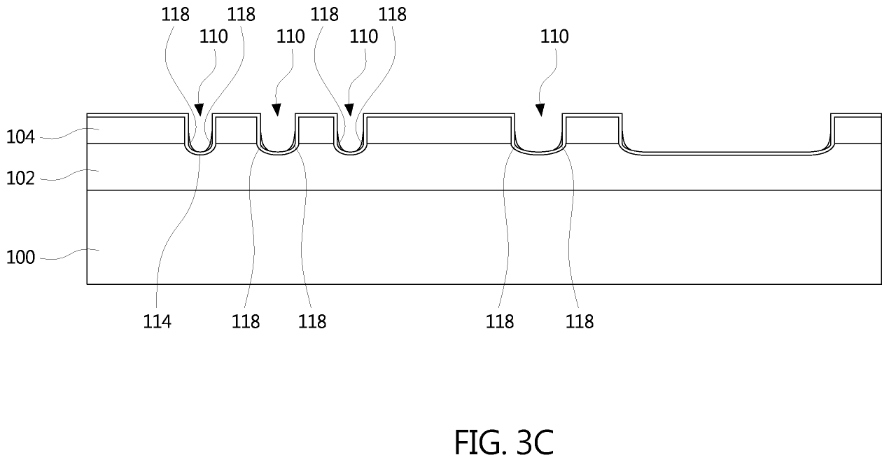

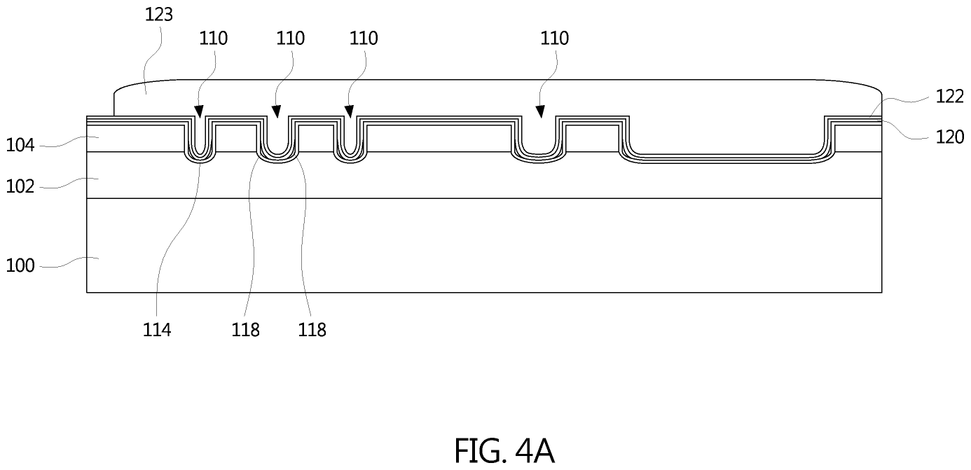

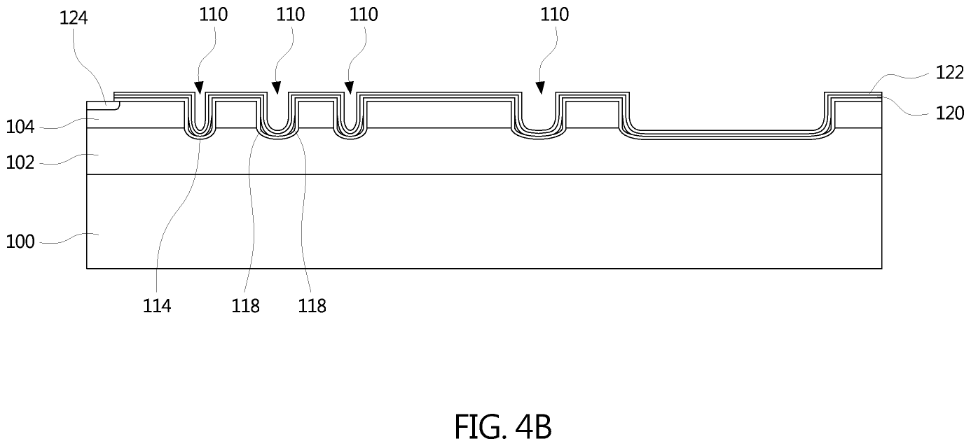

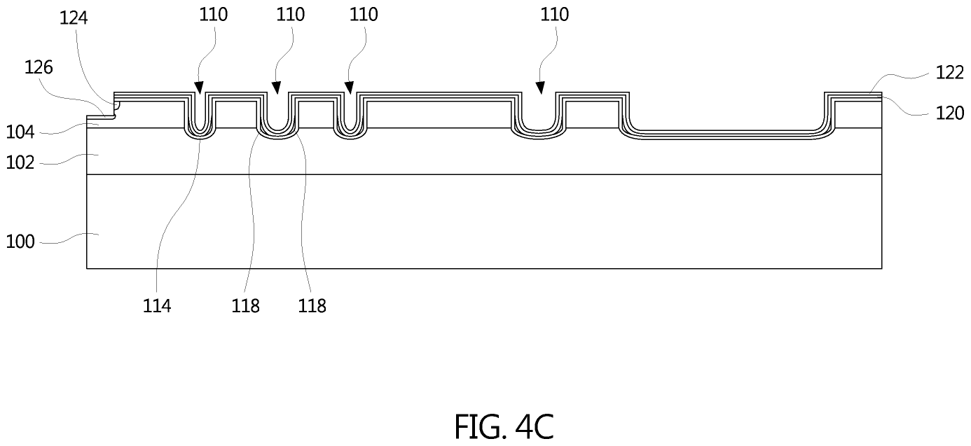

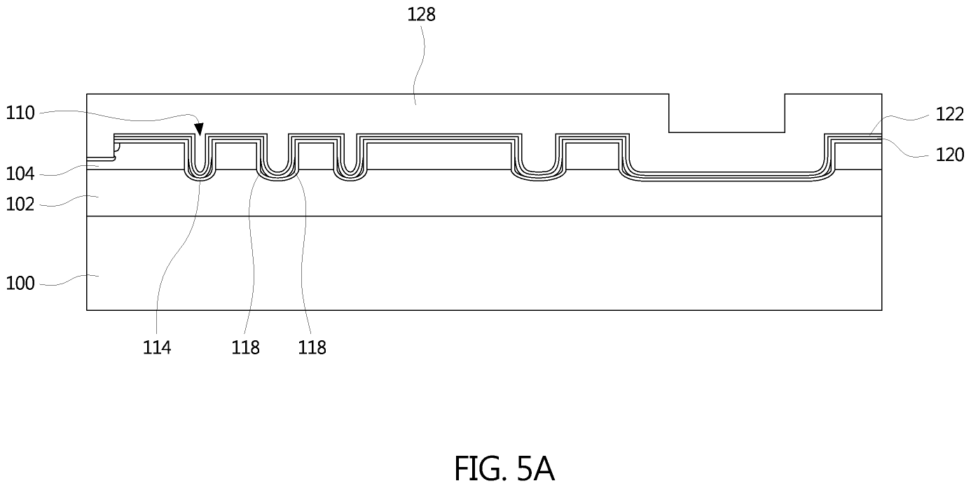

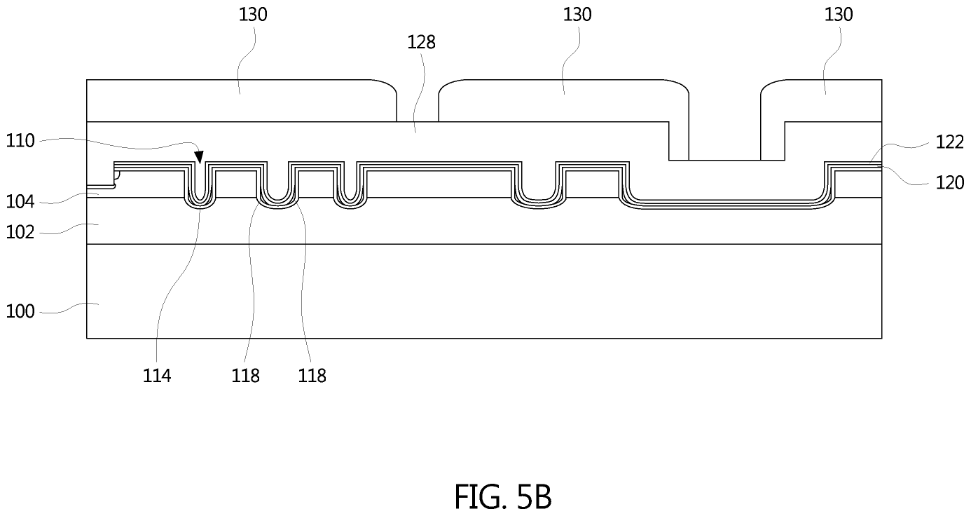

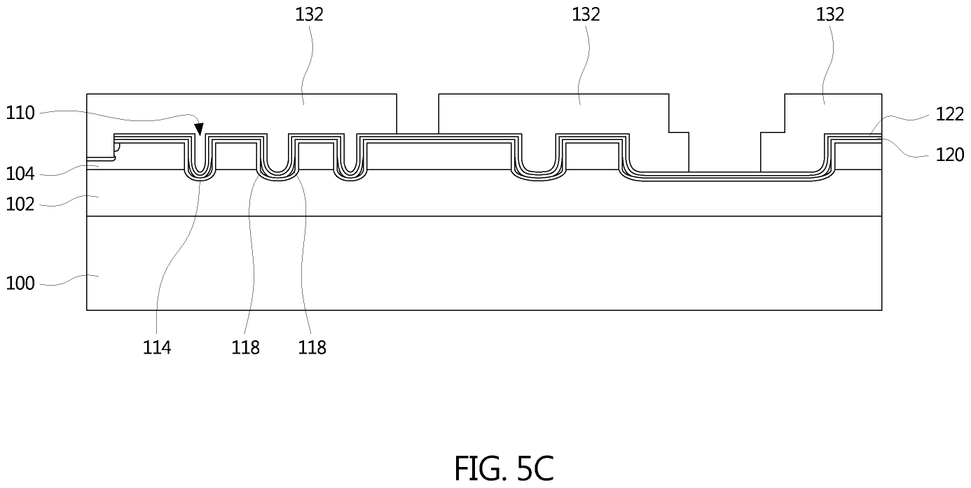

FIG. 2A and FIG. 2B are schematic cross sectional views of forming and removing a sacrifice oxide layer 112 in steps of a fabricating process in sequence according to an embodiment of the instant disclosure. As shown in FIG. 2A, the sacrifice oxide layer 112 is formed in each trench ring 110 in an oxidizing manner. Due to the influence of thermal effect, the doped zone 104 diffuses, and the thickness of the doped zone 104 increases. Next, as shown in FIG. 2B, the sacrifice oxide layer 112 and the hard mask 106 are removed.

FIG. 3A to FIG. 3C are schematic cross sectional views of forming island polycrystalline silicon zones 118 in steps of a fabricating process in sequence according to an embodiment of the instant disclosure. As shown in FIG. 3A, a gate oxide layer 114 is formed above the doped zone 104 in an oxidizing manner and covers each trench ring 110. Next, as shown in FIG. 3B, polycrystalline silicon 116 is deposited on the gate oxide layer 114 in the trench ring 110 and is filled in each trench ring 110 by known deposition technique of polycrystalline silicon such as Chemical Vapor Deposition (CVD) and Physical Vapor Deposition (PVD), or by any other suitable film forming process. It is noted that the width of the trench ring 110 of the termination is about 10 times greater than that of the trench of the main zone, and each trench ring 110 cannot be fully filled by the polycrystalline silicon 116. Next, as shown in FIG. 3C, a known etching process, e.g., anisotropy etching, back etching, or dry etching, is carried out to etch the polycrystalline silicon 116. Since the width of the trench ring 110 of the termination is relatively greater, the two self-aligned island polycrystalline silicon zones 118 are formed on two side walls each trench ring 110 in the process of the back etching of polycrystalline silicon, and the two island polycrystalline silicon zones 118 do not contact with each other

FIG. 4A to FIG. 4C are schematic cross sectional views of forming an insulation oxide layer, a source polycrystalline silicon zone 124, and a heavily doped zone 126 in steps of a fabricating process in sequence according to an embodiment of the instant disclosure. As shown in FIG. 4A, an insulation oxide layer is formed in each trench ring 110 in an oxidizing manner. In the termination structure, the insulation oxide layer is used to cover the two island polycrystalline silicon zones 118 to prevent a subsequent deposited metal layer (referring to a discontinuous metal layer 132 shown in FIG. 5C) from causing the two island polycrystalline silicon zones 118 to be electrically connected to form equal potential. in the embodiment, the step of forming the insulation oxide layer in each trench ring 110 comprises steps in sequence as follows: forming an inner-layer dielectric layer 120 in each trench ring 110 and forming a boro-phospho-silicate glass layer 122 on the inner-layer dielectric layer 120. Next, as shown in FIG. 4A, a photoresist is applied on the insulation oxide layer (the inner-layer dielectric layer 120 and the boro-phospho-silicate glass layer 122) and a mask is used to carry out an exposing and developing process to form a patterned photoresist 123. Next, as shown in FIG. 4B, the patterned photoresist 123 is used as a mask to carry out an etching process of the exposed insulation oxide layer (the inner-layer dielectric layer 120 and the boro-phospho-silicate glass layer 122) on the main zone of the MOSFET (the leftmost periphery in the drawing is the periphery of the main zone of the MOSFET) to form a contact window, and then the patterned photoresist 123 is removed. Then, the first conductive type source polycrystalline silicon zone 124, e.g., an N type source zone, is formed on the doped zone 104 of the main zone via the contact window in an ion implantation manner. Next, as shown in FIG. 4C, a process of blanket body implantation and drive-in is carried out to form the second conductive type heavily doped zone 126, e.g., a P type heavily conductive zone.

FIG. 5A to FIG SC are schematic cross sectional views of forming the discontinuous metal layer 132 in steps of a fabricating process in sequence according to an embodiment of the instant disclosure. As shown in FIG. 5A, a metal layer 128 is deposited above the doped zone 104. Next, as shown in FIG. 5B, a photoresist is applied above the metal layer 128, and a mask is used to carry out an exposing and developing process to form a patterned photoresist 130. Next, as shown in FIG. 5C, an etching process of the metal layer 128 is carried out by the patterned photoresist 130, and then the patterned photoresist 130 is removed. Ultimately, the discontinuous metal layer 132 is formed. The discontinuous metal layer 132 is used to induct lateral potential of the termination structure of the MOSFET to increase lateral breakdown voltage of the termination structure of the MOSFET.

As shown in FIG. 5C, the termination structure of MOSFET according to the embodiment comprises the semiconductor substrate, the doped zone 104, the gate oxide layer 114, the two island polycrystalline silicon zones 118, the insulation oxide layer, and the discontinuous metal layer 132. The semiconductor substrate comprises the substrate 100 and the epitaxial layer 102. The epitaxial layer 102 is formed above the substrate 100. The doped zone 104 is formed on the semiconductor substrate. In particular, the doped zone 104 is formed on the epitaxial layer 102. The doped zone 104 comprises a plurality of trench rings 110. The gate oxide layer 114 is formed in each trench ring 110. The two island polycrystalline silicon zones 118 are formed on the gate oxide layers 114 of the two side walls of each trench ring 110. The two island polycrystalline silicon zones 118 do not contact with each other, The insulation oxide layer covers above the two island polycrystalline silicon zones 118. In particular, the insulation oxide layer comprises the inner-layer dielectric layer 120 and the boro-phospho-silicate glass layer 122. The boro-phospho-silicate glass layer 122 is formed above the inner-layer dielectric layer 120. The discontinuous metal layer 132 is formed above the gate oxide layer 114 and the insulation oxide layer in the doped zone doped zone 104 and the trench ring 110.

In an embodiment, the two island polycrystalline silicon zones are made of polycrystalline silicon, doped polycrystalline silicon, metal, amorphous silicon, or the combination thereof, and the gate oxide layer is made of silica.

Table 1 and Table 2 as follows are results of simulation of the depth of the guard ring and the breakdown voltage of the termination structures of the prior art and the instant disclosure under the same conditions of the epitaxial layers. As shown in Table 1, the breakdown voltage of the termination structure of the instant disclosure is irrelevant to the depth of the guard ring; therefore, the design of components is of more flexibility. Based upon the effect of the two island polycrystalline silicon zones not contacting with each other and the discontinuous metal layer in each trench ring, the lateral breakdown voltage can be inducted, and the sum of the lateral breakdown voltage can be increased by dividing voltage, so as to make a breakdown point of components occur in the main zone. As shown in Table 2, the breakdown voltage and the depth of the guard ring of the termination structure of the prior art are in direct ratio. The greater the depth of the guard ring is, the more the thermal budge for carrying out implantation and diffusion of impurity is required. In addition, thicker epitaxial layer is required to receive the guard ring, such that the on-resistance is increased.

TABLE 1
Termination Structures of Embodiment of the Instant disclosure

| Depth of | Resistance of | Depth of | Breakdown |
|---|---|---|---|
| Epitaxial | Epitaxial Layer | Guard Ring | Voltage |
| Layer (μm) | (Ω-cm) | (μm) | (V) |
| 12 | 1.2 | 1.5 | 131.7 |
| | | 1.8 | 130.5 |
| | | 2.3 | 128.8 |
| | 1.3 | 1.5 | 135.9 |
| | | 1.8 | 134.7 |
| | | 2.3 | 133.2. |
| | 1.6 | 1.5 | 147.0 |
| | | 1.8 | 151.7 |
| | | 2.3 | 154.3 |
| | 1.8 | 1.5 | 148.5 |
| | | 1.8 | 153.3 |
| | | 2.3 | 160.4 |

TABLE 2
Termination Structures of Prior Art

| Depth of | Resistance of | Depth of | Breakdown |
|---|---|---|---|
| Epitaxial | Epitaxial Layer | Guard Ring | Voltage |
| Layer (μm) | (Ω-cm) | (μm) | (V) |
| 12 | 1.2 | 2 | 115.6 |
| | | 2.3 | 117.7 |
| | | 2.6 | 118.8 |
| | 1.3 | 2 | 121.5 |
| | | 2.3 | 122.9 |
| | | 2.6 | 124.1 |
| | | 2 | 135.8 |
| | 1.6 | 2.3 | 137.3 |
| | 2.6 | | 139.0 |
| | 1.8 | 2 | 144.0 |
| | | 2.3 | 145,6 |
| | | 2.6 | 151.1 |

The termination structure of MOSFET according to the instant disclosure is especially suitable to the termination structure of trench MOSFET. The trench ring can be formed on the termination while the trench is formed on the main zone; therefore, the fabricating processes can be easily integrated, and the main zone and the termination can be fabricated by the same three-layer mask process (including the step of forming the patterned photoresists 108, 123, and 130). The time of the fabricating process can be reduced, and the cost of products can be lowered. In addition, comparing to the known well zone guard ring, the termination structure according to the instant disclosure adopts trench guard ring (so-called trench ring); therefore, the length of the guard ring can be shortened, and the area of chip can be reduced. In terms of the properties of components, the sensitivities of the breakdown voltage and the depth of the guard ring can be lowered. In addition, the yield and stability can be improved,

The purpose of the above recitation is for illustration. Every specific detail is for thorough understanding of the instant disclosure. People skilled in the art shall practice the instant disclosure without the need of certain detail therein. In other embodiments, known structures and devices are not shown in block diagrams. There may be a medium structure between components in the drawings. The components may include additional input and output, which are not shown the drawings in detail.

While the recitation includes “a component A being connected (or coupled) to a component B,” the component A may be directly connected (or coupled) to the component

B, or may be indirectly connected (or coupled) to the component B via a component C. While the recitation includes “a component (feature, structure, procedure, or property) A resulting in a component (feature, structure, procedure, or property) B,” it means that A is at least a part of a cause of B, or that there is another component (feature, structure, procedure, or property) which assists in causing B. The terms of “may,” “might,” “can,” or “could” mean a component (feature, structure, procedure, or property) not limited by the instant disclosure. The number or amount recited in the instant disclosure is not limited to “a,” “an,” or “one.”

Regardless of the objects, means, or results of the invention, the features are significantly distinct from prior arts. It is noted that the embodiments are for illustratively showing the theory and function of the invention, but not for limiting the scope of the invention. While the instant disclosure has been described by way of example and in terms of the preferred embodiments, it is to be understood that the instant disclosure needs not be limited to the disclosed embodiments. Anyone skilled in the art may make modification and change to the embodiments without contradicting the theory and spirit of the invention. It shall be understood that for people in the art, various modifications and improvements of the disclosed components of the instant disclosure within the spirit of the instant disclosure are obvious and covered under the scope of the instant disclosure. The disclosed devices and methods shall not be limited and are covered by the scope of the appended claims.

What is claimed is:

1. A fabricating method of a termination structure of MOSFET, comprising steps of:
forming a doped zone on a semiconductor substrate;
forming a plurality of trench rings in the doped zone;
forming a gate oxide layer in each of the trench rings;
depositing a polycrystalline silicon above the gate oxide layer;
carrying out a back etching process of the polycrystalline silicon to form two self-aligned island polycrystalline silicon zones on two side walls of each of the trench rings, the two island polycrystalline silicon zones being not contact with each other;
forming an insulation oxide layer in each of the trench rings; and
covering the doped zone with a metal layer, and laying out the metal layer to form a discontinuous metal layer.

2. The fabricating method of the termination structure of MOSFET of claim 1, wherein the step of forming the trench rings in the doped zone comprises steps of depositing a hard mask above the doped zone;
forming a patterned photoresist on the hard mask;
laying out the hard mask to form the trench rings by the patterned photoresist; and
carrying out a dry etching process to form the trench rings in the doped zone.

3. The fabricating method of the termination structure of MOSFET of claim 1, after the step of forming the trench rings in the doped zone and before the step of forming the gate oxide layer in each of the trench rings, further comprising a step of:
forming a sacrifice oxide layer in each of the trench rings and then removing the sacrifice oxide layer.

4. The fabricating method of the termination structure of MOSFET of claim 1, after the step of forming the insulation oxide layer in each of the trench rings and before the step of covering the doped zone with the metal layer, further comprising steps of:
forming a patterned photoresist on the insulation oxide layer;
carrying out an etching process of the exposed insulation oxide layer on a main zone of the MOSFET by the patterned photoresist to form a contact window and then removing the patterned photoresist; and
forming a source polycrystalline silicon zone and a heavily doped zone on the doped zone of the main zone via the contact window.

5. The fabricating method of the termination structure of MOSFET of claim 1, wherein the step of forming the insulation oxide layer in each of the trench rings comprises steps of:
forming an inner-layer dielectric layer in each of the trench rings; and
forming a boro-phospho-silicate glass layer on the inner-layer dielectric layer.

6. The fabricating method of the termination structure of MOSFET of claim 1, wherein the step of laying out the metal layer to form the discontinuous metal layer comprises steps of:
depositing the metal layer above the doped zone;
forming the patterned photoresist above the metal layer;
carrying out an etching process of the metal layer by the patterned photoresist and then removing the patterned photoresist; and
forming the discontinuous metal layer.

7. A termination structure of MOSFET, comprising:
a semiconductor substrate:
a doped zone formed on the semiconductor substrate, the doped zone comprising a plurality of trench rings;
a gate oxide layer formed in each of the trench rings;
two island polycrystalline silicon zones formed on the gate oxide layer of two side walls of each of the trench rings, the two island polycrystalline silicon zones being not contact with each other;
an insulation oxide layer covering above the two island polycrystalline silicon zones; and
a discontinuous metal layer formed above the gate oxide layer and the insulation oxide layer in the doped zone and the trench ring.

8. The termination structure of MOSFET of claim 7, wherein the two island polycrystalline silicon zones are made of polycrystalline silicon, doped polycrystalline silicon, metal, amorphous silicon, or the combination thereof, and the gate oxide layer is made of silica.

9. The termination structure of MOSFET of claim 7, wherein the semiconductor substrate comprises:
a substrate; and
an epitaxial layer formed above the substrate.

10. The termination structure of MOSFET of claim 7, wherein the insulation oxide layer comprises:
an inner-layer dielectric layer; and
a boro-phospho-silicate glass layer formed above the inner-layer dielectric layer.
